(19) United States
(12) Patent Application Publication
(10) Pub. No.: US 2015/0254545 A1
(43) Pub. Date: Sep. 10, 2015

(54) MEMORY CARD

(71) Applicant: Kabushiki Kaisha Toshiba, Minato-ku (JP)

(72) Inventors: Hironari UEHARA, Kamakura (JP); Akihiro IIDA, Kamakura (JP); Junichi ASADA, Sagamihara (JP)

(73) Assignee: Kabushiki Kaisha Toshiba, Minato-ku (JP)

(21) Appl. No.: 14/468,454

(22) Filed: Aug. 26, 2014

Related U.S. Application Data
(60) Provisional application No. 61/950,537, filed on Mar. 10, 2014.

(51) Int. Cl. G06K 19/073; G11C 7/24

(52) U.S. Cl. CPC G06K 19/07345; G11C 7/24

(57) ABSTRACT

According to one embodiment, a memory card includes a housing and a switch. The housing includes a first surface and a second surface. The second surface is opposite to the first surface. The switch includes a first part, a second part, and a third part. The first part is disposed outside from the housing. The third part is disposed in the housing. The second part is connected to both the first part and the third part. The third part is in contact with both the first surface and the second surface.

### CROSS-REFERENCE TO RELATED APPLICATIONS

This application claims the benefit of U.S. Provisional Application No. 61/950,537, filed Mar. 10, 2014, the entire contents of which are incorporated herein by reference.

### FIELD

Embodiments described herein relate generally to a memory card provided with a semiconductor storage device.

### BACKGROUND

For example, a memory card having a write protection function is known.

### BRIEF DESCRIPTION OF THE DRAWINGS

FIG. 1 is a plan view of a memory card according to a first embodiment;

FIG. 2 is a side view of the memory card as shown in FIG. 1;

FIG. 3 is a cross-sectional view taken along line in FIG. 1;

FIG. 4 is a cross-sectional view of part of a memory card according to a second embodiment;

FIG. 5 is a cross-sectional view of part of a memory card according to a third embodiment;

FIG. 6 is a cross-sectional view of part of a memory card according to a fourth embodiment; and

FIGS. 7A-7E show modifications of the fourth embodiment and also part of FIG. 6.

### DETAILED DESCRIPTION

In general, according to one embodiment, a memory card includes a housing and a switch. The housing includes a first surface and a second surface. The second surface is opposite to the first surface. The switch includes a first part, a second part, and a third part. The first part is disposed outside from the housing. The third part is disposed in the housing. The second part is connected to both the first part and the third part. The third part is in contact with both the first surface and the second surface.

A memory card such as an SD™ card includes a write protection (hereinafter referred to as WP) switch in a case body. The WP switch is slidably held in the case body. It is possible to distinguish a writable state and a write-protect state from each other by referring to a position of the WP switch with respect to the case body.

The case body comprises an upper case and a lower case, and the WP switch is slidably held by the upper case and the lower case.

However, if a great external force is applied to the WP switch, there is a possibility that the WP switch will be easily detached from the case body. If the switch is detached, a host device recognizes that the memory card is in a write-protect state, and only readout is thus allowed. It is therefore desired that a WP switch is provided which has a structure for preventing it from being easily detached from the case body.

Embodiments will be described hereinafter with reference to the accompanying drawings. With respect to each of the embodiments, structural elements identical to those in the other embodiments will be denoted by the same reference numerals as in the other embodiments, and in the embodiments, only different structural elements will be explained.

### First Embodiment

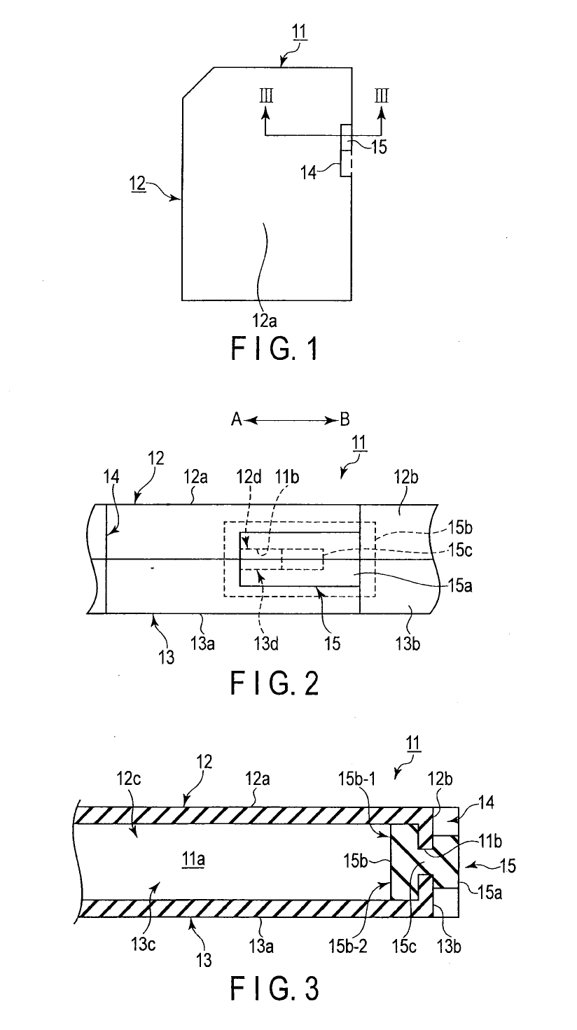

FIGS. 1-3 show a first embodiment. As shown in FIGS. 1-3, a case body (hereinafter also referred to as a housing) 11 of a memory card such as an SD card comprises a first case 12 and a second case 13 which correspond to an upper case and a lower case, respectively.

The first case 12 includes a first surface 12a having, e.g., five sides as shown in FIG. 1, and a first side surface 12b formed on a periphery of the first surface 12a as shown in FIGS. 2 and 3; and the first surface 12a and the first side surface 12b form a first accommodation portion 12c.

The second case 13, as well as the first case 12, includes a second surface 13a having, e.g., five sides, and a second side surface 13b on a periphery of the second surface 13a, as shown in FIGS. 2 and 3; and the second surface 13a and the second side surface 13b form a second accommodation portion 13c.

The first side surface 12b of the first case 12 and the second side surface 13b of the second case 13 are bonded to each other to form the housing 11. In the housing 11, the first accommodation portion 12c and the second accommodation portion 13c form an accommodation portion 11a. In the accommodation portion 11a, a semiconductor memory not shown is provided.

As shown in FIGS. 1 and 2, a notch portion 14 is formed in a side surface of the housing 11, and the SW switch 15 is slidably engaged with the notch portion 14.

The WP switch 15 has no electrical contact. After the memory card according to the first embodiment is inserted into the host device, the host device checks a position of the WP switch 15 to determine whether it indicates the write-protect state or the writable state. For example, a position of the WP switch 15 as shown by a solid line in FIG. 1 indicates the writable state, and that as shown by a broken line in FIG. 1 indicates the write-protect state. If the WP switch 15 is detached from the housing 11 by an external force, the host device determines that the write-protect state as shown by the broken line is indicated, and writing to the SD card is inhibited.

As shown in FIG. 2, an opening portion 11b is formed in a side surface of the notch portion 14 of the housing 11. That is, the opening portion 11b is formed to comprise a first notch portion 12d formed in part of the first side surface 12b and a second notch portion 13d formed in part of the second side surface 13b. In the opening portion 11b, the WP switch 15 is held slidable in directions A and B indicated by a double-pointed arrow.

As shown in FIGS. 2 and 3, the WP switch 15 comprises an operation portion 15a, an engagement portion 15b, and a shaft portion 15c provided between the operation portion 15a and the engagement portion 15b. With respect to a line extending through a center of the shaft portion 15c, each of the operation portion 15a and the engagement portion 15b is symmetrically formed.

The operation portion 15a is located outward of the first side surface 12b of the first case 12 and the second side surface 13b of the second case 13 (i.e., it is located outside the housing 11), and is operated by a user.

The engagement portion 15b is located inward of the first side surface 12b of the first case 12 and the second side surface 13b of the second case 13 (i.e., it is located in the inside of the housing 11). The shaft portion 15c is connected to the operation portion 15a and the engagement portion 15b. Also, the shaft portion 15c is movably located in the opening portion 11b.

Furthermore, the operation portion 15a is in contact with an outer side of the first side surface 12b of the first case 12 and an outer side of the second side surface 13b of the second case 13. The engagement portion 15b includes a first part 15b-1 and a second part 15b-2. The first part 15b-1 is in contact with an inner surface of the first side surface 12b of the first case 12 and an inner surface of the first surface 12a thereof, and the second part 15b-2 is in contact with an inner surface of the second side surface 13b of the second case 13 and an inner surface of the second surface 13a thereof. Thus, the WP switch 15 is engaged with both the first case 12 and the second case 13. Therefore, for example, even if an external force is applied to the first case 12 corresponding to the upper case, or even if it is applied to the second case 13 corresponding to the lower case, the WP switch 15 can be prevented from being detached from the housing 11.

According to the first embodiment, the WP switch 15 has a symmetrical structure with respect to a line extending through the center of the shaft portion 15c. To be more specific, each of the operation portion 15a and the engagement portion 15b is symmetrically formed in a vertical direction with respect to the line extending through the center of the shaft portion 15c, and the operation portion 15a and the engagement portion 15b are slidably engaged with the first side surface 12b of the first case 12 and the second side surface 13b of the second case 13. Thus, for example, even if an external force is applied to the first case 12 corresponding to the upper case or to the second case 13 corresponding to the lower case, the WP switch 15 can be prevented from being detached from the housing 11. Therefore, the reliability of the WP switch 15 can be improved.

### Second Embodiment

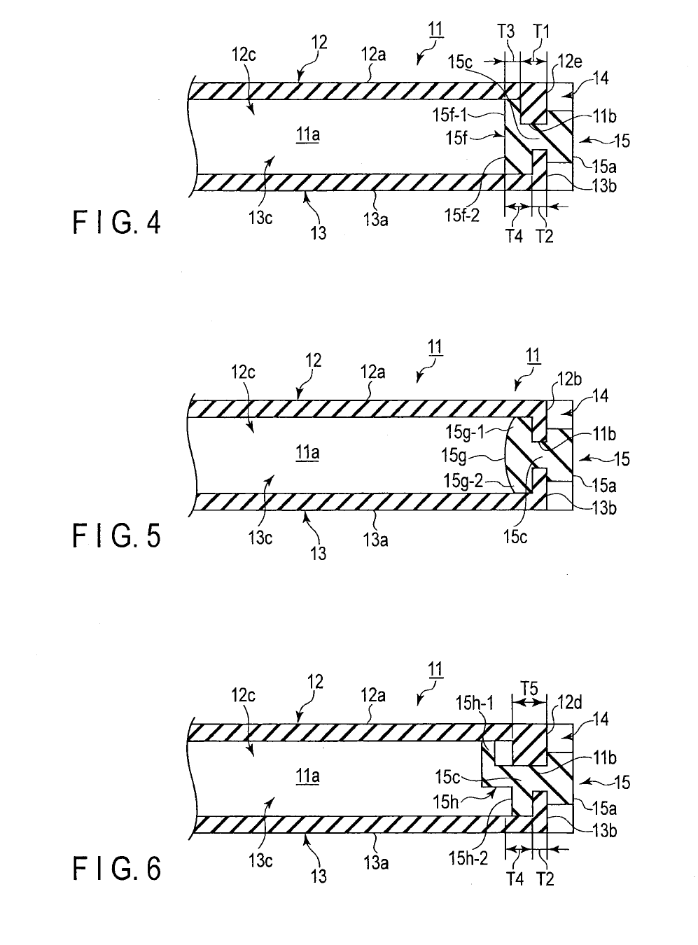

FIG. 4 shows a second embodiment, which is a modification of the first embodiment. In the first embodiment, each of the operation portion 15a and the engagement portion 15b is symmetrically formed with respect to the line extending through the center of the shaft portion 15c. On the other hand, an engagement portion 15f is asymmetrically formed with respect to the center of the shaft portion 15c.

To be more specific, referring to FIG. 4, in a WP switch 15, the engagement portion 15f includes a first part 15f-1 and a second part 15f-2. The first part 15f-1 is in contact with an inner surface of a first side surface 12e of the first case 12 and an inner surface of the first surface 12a, and the second part 15f-2 is in contact with an inner surface of the second side surface 13b of the second case 13 and an inner surface of the second surface 13a.

A thickness T1 of the first side surface 12e is greater than a thickness T2 of the second side surface 13b, and a thickness T3 of the first part 15f-1 of the engagement portion 15f is smaller than a thickness T4 of the second part 15f-2 thereof. The sum of the thickness T1 of the first side surface 12e and the thickness T3 of the first part 15f-1 of the engagement portion 15f is substantially equal to the sum of the thickness T2 of the second side surface 13b and the thickness T4 of the second part 15f-2 of the engagement portion 15f.

According to the second embodiment, the engagement portion 15f of the WP switch 15 includes: the first part 15f-1, which is in contact with the inner surface of the first side surface 12e of the first case 12 and the first surface 12a; and the second part 15f-2, which is in contact with the inner surface of the second side surface 13b of the second case 13 and the second surface 13a. Thus, the shaft portion 15c, the operation portion 15a and the engagement portion 15f of the WP switch 15 are held by the first side surface 12e of the first case 12 and the second side surface 13b of the second case 13. Therefore, for example, even if an external force is applied to the first case 12 corresponding to the upper case or to the second case 13 corresponding to the lower case, the WP switch 15 can be prevented from being detached from the housing 11, and thus the reliability of the WP switch 15 can be improved.

Furthermore, the sum of the thickness T3 of the first part 15f-1 of the engagement portion 15f and the thickness T1 of the first side surface 12e of the first case 12 is substantially equal to the sum of the thickness T2 of the second side surface 13b of the second case 13 and the thickness T4 of the second part 15f-2 of the engagement portion 15f. Thus, the volume of the housing 11 can be prevented from being decreased.

### Third Embodiment

FIG. 5 shows a third embodiment, which is a modification of the first embodiment. In the first embodiment, a surface located opposite to a surface where the shaft of the engagement portion 15b is provided is made flat. On the other hand, in the third embodiment, a surface located opposite to a surface where a shaft portion 15c of an engagement portion 15g is provided is curved in the shape of a convex surface. To be more specific, as shown in FIG. 5, in a WP switch 15, the engagement portion 15g has a thickness which varies such that it is the greatest at its center portion corresponding in position to the shaft portion 15c, and it gradually decreases toward the first surface 12a of the first case 12 and the second surface 13a of the second case 13. This feature can reduce a contact resistance between a first part 15g-1 of the engagement portion 15g and the first surface 12a, and a frictional resistance between a second part 15g-2 of the engagement portion 15g and the second surface 13a. Also, due to the above structure, in the engagement portion 15g, a surface located opposite to a surface where the shaft portion 15c is provided is curved to project in a direction away from the shaft portion 15c.

It should be noted that although the engagement portion 15g of the WP switch 15 according to the third embodiment has a thickness which is set such that it is the greatest at its center portion corresponding in position to the shaft portion 15c, setting of the thickness is not limited to the above setting. For example, the thickness may be set such that it is the greatest at part located at an upper or lower position than the center portion corresponding in position to the shaft portion 15c.

According to the third embodiment, the WP switch 15 is symmetrically formed with respect to the line extending through the center of the shaft portion 15c. To be more specific, each of the operation portion 15a and the engagement portion 15g is symmetrically formed in the vertical direction with respect to the line extending through the shaft portion 15c; and the operation portion 15a and the engagement portion 15g are slidably engaged with inner surfaces of the first surface 12a and the first side surface 12b of the first case 12, and also with inner surfaces of the second surface 13a and the second side surface 13b of the second case 13. Thus, for example, even if an external force is applied to the first case 12 corresponding to the upper case, or to the second case 13 corresponding to the lower case, the WP switch 15 can be prevented from being detached from the housing 11. Therefore, the reliability of the WP switch 15 can be improved.

Furthermore, the thickness of the engagement portion 15g is set such that it is the greatest at the center portion corresponding in position to the shaft portion 15c, and gradually decreases toward the first surface 12a of the first case 12 and the second surface 13a of the second case 13. Thus, a contact resistance between the first part 15g-1 of the engagement portion 15g and the first surface 12a and a frictional resistance between a second part 15g-2 of the engagement portion 15g and the second surface 13a can be reduced.

In addition, the surface located opposite to the surface where the shaft portion 15c of the engagement portion 15g is provided is a convex surface. Thus, in order to reduce the frictional resistances between the inner surface of the first surface 12a and the first part 15g-1 and between the inner surface of the second surface 13a and the second part 15g-2, if end portions of the engagement portion 15g are formed thinner, since the center portion of the engagement portion 15g is thicker than the end portions, a strength of the engagement portion 15g can be maintained. Thus, the reliability of the WP switch 15 can be improved.

### Fourth Embodiment

FIG. 6 shows a fourth embodiment, which is a modification of, e.g., the second embodiment. In the second embodiment, the engagement portion 15f of the WP switch 15 is asymmetrically formed with respect to the line extending through the center of the shaft portion 15c, and is in contact with the inner surface of the second side surface 13b. On the other hand, in the fourth embodiment, an engagement portion 15h includes part not contacting a first side surface 12d of the first case 12.

To be more specific, referring to FIG. 6, the engagement portion 15h includes a first part 15h-1 and a second part 15h-2. The first part 15h-1 is in contact with the first surface 12a of the first case 12, and separated from the first side surface 12d; and the second part 15h-2 is in contact with the second side surface 13b and the second surface 13a.

Furthermore, a thickness T5 of the first side surface 12d is substantially equal to the sum of a thickness T2 of the second side surface 13b and a thickness T4 of the second part 15h-2 of the engagement portion 15h.

For example, the first part 15h-1 and the second part 15h-2 are made to have the same thickness; however, they may be to have different thicknesses. Furthermore, the thickness T5 of the first side surface 12d is made greater than that T2 of the second side surface 13b; however, they may be made equal to each other.

According to the fourth embodiment, in the WP switch 15, the shaft portion 15c and the second part 15h-2 are pushed by the first side surface 12d having the thickness T5 in the first case 12, and the first part 15h-1 is separated from the first side surface 12d and in contact with the inner surface of the first surface 12a. Thus, for example, even if an external force is applied to the first case 12 corresponding to the upper case or to the second case 13 corresponding to the lower case, the WP switch 15 can be prevented from being detached from the housing 11. Therefore, the reliability of the WP switch 15 can be improved.

In addition, the first part 15h-1 is separated from the first side surface 12d of the first case 12. That is, the distance between the operation portion 15a and the first part 15h-1 of the engagement portion 15h in the WP switch 15 is greater than the thickness T5 of the first side surface 12d of the first case 12. Thus, at the time of assembling the case body 11, the first case 12 can be easily bonded to the second case 13, by attaching the WP switch 15 which is minute to the second side surface 13b of the second case 13 beforehand for example. Therefore, assembly can be made easier.

### Modifications

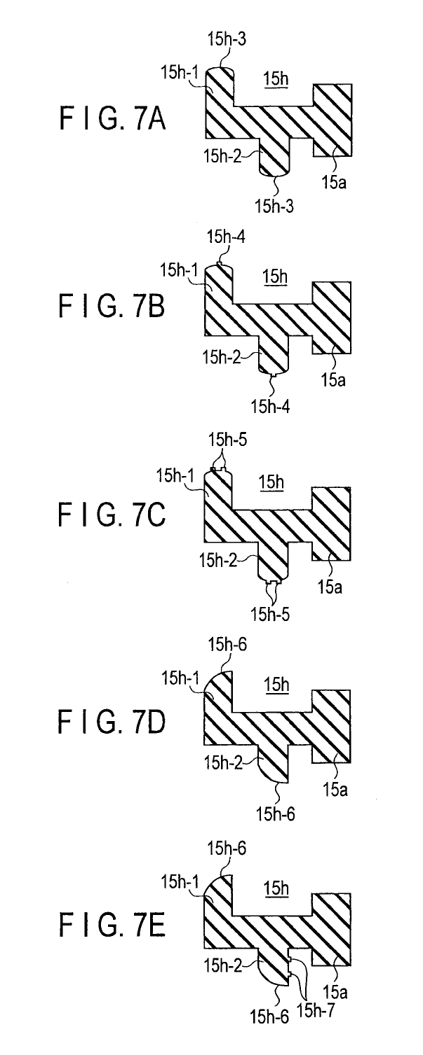

FIGS. 7A-7E show modifications of the fourth embodiment. It is hoped that the WP switch 15 has a good operability to such a given extent that its set position is not easily varied when an SD card is loaded into the host device. In view of this point, the modifications are intended to suitably reduce the frictional resistance of the WP watch 15.

Referring to FIG. 7A, distal end portions of first part 15h-1 and second part 15h-2 of an engagement portion 15h include curved surfaces 15-3, which are brought into contact with the first surface 12a and the second surface 13a.

According to a structure as shown in FIG. 7A, contact areas between first part 15h-1 of an engagement portion 15h and the first surface 12a and between second part 15h-2 of the engagement portion 15h and the second surface 13a can be reduced, and frictional resistances between the first part 15h-1 of the engagement portion 15h and the first surface 12a and between the second part 15h-2 of the engagement portion 15h and the second surface 13a can be suitably reduced.

FIGS. 7B and 7C show further modifications of the structure as shown in FIG. 7A.

Referring to FIG. 7B, each of distal end portions of first parts 15h-1 and 15h-2 of an engagement portion 15h includes a single projection 15h-4.

Referring to FIG. 7C, each of distal end portions of first parts 15h-1 and 15h-2 of an engagement portion 15h includes two projections 15h-5.

The projections 15h-4 and 15h-5 are brought into contact with the first surface 12a and the second surface 13a.

As shown in FIGS. 7B and 7C, one projection 15h-4 or two projections 15h-5 are provided at each of the distal end portions of the first parts 15h-1 and 15h-2 of the engagement portion 15h, and brought into contact with the first surface 12a and the second surface 13a. By virtue of this structure, it is possible to suitably the frictional resistances between the projections 15h-4 or 15h-5 and the first surface 12a and the second surface 13a.

It should be noted that in the structures as shown in FIGS. 7B and 7C, it is not always necessary to curve the distal end portions of the first part 15h-1 and second part 15-2 of the engagement portion 15h; that is, as shown in FIG. 6, the distal end portions may be made flat, and at each of the flat distal end portions, a single projection 15h-4 or two projections 15h-5 may be provided.

Referring to FIG. 7D, a first part 15h-1 of an engagement portion 15h includes an inclined portion 15h-6 having a surface which is located opposite to the first side surface 12b to incline such that a width of the inclined portion 15h-6 decreases toward its distal end; and a second part 15h-2 of the engagement portion 15h includes an inclined portion 15h-6 having a surface which is located opposite to the second side surface 13b to incline such that a width of the inclined portion 15h-6 decreases toward its distal end. The first part 15h-1 and second part 15h-2, which have distal ends tapered in the above manner, are brought into contact with the first surface 12a and the second surface 13a, respectively.

Since the first part 15h-1 and second part 15h-2 having tapered distal ends as shown in FIG. 7D are brought into contact with the first surface 12a and the second surface 13a, the frictional resistances between the first part 15h-1 and the first surface 12a and between the second part 15h-2 and the second surface 13a can be suitably reduced.

FIG. 7E shows a further modification of the structure as shown in FIG. 7D, which is intended to reduce a frictional resistance between the second side surface 13b and a second part 15h-2 of an engagement portion 15.

Referring to FIG. 7E, a surface of the second part 15h-2 which is brought into contact with the second side surface 13b includes, e.g., two projections 15h-7.

In the structure as shown in FIG. 7E, in the second part 15h-2 of the engagement portion 15h, a tapered distal end of the second part 15h-2 is brought into contact with the second surface 13a, and the projections 15h-7 of the second part 15h-2 are brought into contact with the second side surface 13b. Thus, the frictional resistances between the second surface 13a and the second part 15h-2 and between the second side surface 13b and the second part 15h-2 can be suitably set.

It should be noted that both the first part 15h-1 and the second part 15-2 of the engagement portion 15h include respective curved surfaces 15h-3, respective projections 15h-4 or projections 15h-5 or respective inclined portions 15h-6; however, they do not always need to do so; that is, at least one of the first part 15h-1 and the second part 15h-2 may have include a curved surface 15-3, a projection 15h-4, projections 15h-5 or an inclined portion 15h-6.

Furthermore, the modifications as shown in FIGS. 7A-7E are obtained by modifying the fourth embodiment; however, the embodiment to be modified in the above manners is not limited to the fourth embodiment, i.e., it is possible to obtain modifications by modifying any of the first to third embodiments in the above manners.

The above explanations of the first to fourth embodiments are given with respect to the case where they are applied to the SD™ card by way of example. However, application of the embodiments is not limited to such a case; that is, the embodiments can be applied to, e.g., a memory card provided with a WP switch.

The memory card includes, e.g., a NAND type flash memory, which also includes a memory cell array.

A memory cell array formation may be disclosed in U.S. patent application Ser. No. 12/407,403 filed on Mar. 19, 2009, and the entire contents of U.S. patent application Ser. No. 12/407,403 are incorporated by reference herein.

Furthermore, a memory cell array formation may be disclosed in U.S. patent application Ser. No. 12/406,524 filed on Mar. 18, 2009, and the entire contents of U.S. patent application Ser. No. 12/406,524 are incorporated by reference herein.

Furthermore, a memory cell array formation may be disclosed in U.S. patent application Ser. No. 12/679,991 filed on Mar. 25, 2010, and the entire contents of U.S. patent application Ser. No. 12/679,991 are incorporated by reference herein.

Furthermore, a memory cell array formation may be disclosed in U.S. patent application Ser. No. 12/532,030 filed on Mar. 23, 2009, and the entire contents of U.S. patent application Ser. No. 12/532,030 are incorporated by reference herein.

Furthermore, a memory cell array formation may be disclosed in U.S. patent application Ser. No. 10/155,086 filed on May 28, 2002, and the entire contents of U.S. patent application Ser. No. 10/155,086 are incorporated by reference herein.

In addition, a memory cell includes a charge-storage layer which is provided on a semiconductor substrate (silicon substrate), with a tunnel insulating film having a film thickness of 4 to 10 nm interposed between the charge-storage layer and the semiconductor substrate. The charge-storage layer can be made to have a lamination structure of an insulating film such as SiN or SiON having a film thickness of 2 to 3 nm and polysilicon having a film thickness of 3 to 8 nm. To the polysilicon, metal such as Ru may be added. On the charge-storage layer, an insulating film is provided. The insulating, film includes a silicon oxide film having a film thickness of 4 to 10 nm, which is sandwiched between, e.g., a lower layer High-k film having a film thickness of 3 to 10 nm and an upper layer High-k film having a film thickness of 3 to 10 nm. As the High-k film, HfO, etc. are present. Also, the film thickness of the silicon oxide film can be made greater than that of the High-k film. On the insulating film, a control electrode having a film thickness of 30 to 70 nm is formed, with material for work-function adjustment, which has a film thickness of 3 to 10 nm, interposed between the control electrode and the insulating film. The material for work-function adjustment is a metal oxide film such as TaO or a metal nitride film such as TaN. As the control electrode, W, etc. can be applied.

Furthermore, air gaps can be formed between memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory card comprising:
a housing including a first surface and a second surface, the second surface being opposite to the first surface; and
a switch including a first part, a second part, and a third part, the first part being disposed outside from the housing, the third part being disposed in the housing, the second part being connected to both the first part and the third part, the third part being in contact with both the first surface and the second surface.

2. The memory card according to claim 1, wherein
the third part includes symmetrical structure to a line passing through a center of the second part.

3. The memory card according to claim 1, wherein
the first surface includes a first side surface, and the second surface includes a second side surface.

4. The memory card according to claim 3, wherein
the third part includes a first portion being in contact with the first side surface and a second portion being in contact with the second side surface.

5. The memory card according to claim 3, wherein
the third part includes a convex portion on an opposite side of a side where the second part is connected.

6. The memory card according to claim 3, wherein
the third part includes asymmetrical structure to a line passing through a center of the second part.

7. The memory card according to claim 6, wherein
a thickness of the first side surface is thicker than that of the second side surface.

8. The memory card according to claim 7, wherein
the thickness of the first side surface is equal to a total of a thickness of the second portion of the third part and a thickness of the second side surface.

9. The memory card according to claim 8, wherein
the thickness of the second portion is thicker than that of the first portion.

10. The memory card according to claim 6, wherein
the third part includes a first portion and a second portion, the first portion is separated from the first side surface of the first case and is in contact with the first surface of the first case, and a second portion is in contact with the second side surface of the second case.

11. The memory card according to claim 10, wherein
at least one of end portions of the first portion and the second portion includes a convex portion.

12. The memory card according to claim 10, wherein
at least one of end portions of the first portion and the second portion includes a projection part.

13. The memory card according to claim 10, wherein
at least one tip of the first portion and the second portions includes a taper portion.

14. The memory card according to claim 13, wherein
the second side surface of the second portion includes at least one projection.

15. A memory card comprising:
a housing including a first case and a second case, the first case including a first surface and a first side surface, and the second case including a second surface and a second side surface;
a switch including a first part, a second part, and a third part, the first part being disposed outside from the housing, the third part being disposed in the housing, the second part being connected to both the first part and the third part, the third part being in contact with both the first surface and the second surface.

16. The memory card according to claim 15, wherein
the third part includes symmetrical structure to a line passing through a center of the second part.

17. The memory card according to claim 16, wherein
the third part includes a first portion being in contact with the first side surface and a second portion being in contact with the second side surface.

18. The memory card according to claim 17, wherein
the third part includes a convex portion on an opposite side of a side where the second part is connected.

19. The memory card according to claim 15, wherein
the third part includes asymmetrical structure to a line passing through a center of the second part.

20. The memory card according to claim 19, wherein
the third part includes a first portion and a second portion, the first portion is separated from the first side surface of the first case and is in contact with the first surface of the first case, and a second portion is in contact with the second side surface of the second case.
